(19) United States
(12) Patent Application Publication
(10) Pub. No.: US 2026/0122998 A1
(43) Pub. Date: Apr. 30, 2026

(54) SEMICONDUCTOR DEVICE HAVING DIRAC SOURCE TRANSISTOR

(71) Applicant: Samsung Electronics Co., Ltd., Suwon-si (KR)

(72) Inventors: Kyungrok KANG, Suwon-si (KR); Byungjin CHO, Cheongju (KR); Taehoon PARK, Suwon-si (KR); Seyoung OH, Cheongju (KR); Ojun KWON, Cheongju (KR); Woojin PARK, Cheongju (KR)

(73) Assignees: Samsung Electronics Co., Ltd., Suwon-si (KR); CHUNGBUK NATIONAL UNIVERSITY INDUSTRY-ACADEMIC COOPERATION FOUNDATION, Chungcheongbuk-do (KR)

(21) Appl. No.: 19/009,011

(22) Filed: Jan. 3, 2025

(30) Foreign Application Priority Data
May 9, 2024 (KR) 10-2024-0061265

(51) Int. Cl. H10D 62/80; H10D 62/10; H10D 62/13; H10D 62/17

(52) U.S. Cl. CPC H10D 62/882; H10D 62/102; H10D 62/124; H10D 62/151; H10D 62/292; H10D 62/875

(57) ABSTRACT

A semiconductor device may include a substrate and a Dirac source transistor. The Dirac source transistor may include a gate electrode on the substrate, a gate dielectric film covering the gate electrode, a semiconductor channel layer including an oxide semiconductor material and covering the gate dielectric film, a Dirac source layer partially covering the semiconductor channel layer, a source electrode connected to the Dirac source layer, and a drain electrode connected to the semiconductor channel layer. The Dirac source layer may at least partially overlap the gate electrode in a vertical direction. The Dirac source layer may be spaced apart from the drain electrode and may be not connected to the drain electrode.

### CROSS-REFERENCE TO RELATED APPLICATION

This application is based on and claims priority under 35 U.S.C. § 119 to Korean Patent Application No. 10-2024-0061265, filed on May 9, 2024, in the Korean Intellectual Property Office, the disclosure of which is incorporated by reference herein in its entirety.

### BACKGROUND

Inventive concepts relate to a semiconductor device, and more particularly, to a semiconductor device having a Dirac source.

Electronic products may be required to have high performance and/or high speeds according to rapid development of electronic industries and user's demands, and accordingly, the high performance and/or high speeds also may be required for semiconductor devices used in the electronic products.

### SUMMARY

Inventive concepts provide a semiconductor device including a Dirac source transistor having reduced power consumption to achieve high performance and/or high speed.

According to an embodiment of inventive concepts, a semiconductor device may include a substrate; and a Dirac source transistor. The Dirac source transistor may include a gate electrode on the substrate, a gate dielectric film covering the gate electrode, a semiconductor channel layer including an oxide semiconductor material and covering the gate dielectric film, a Dirac source layer partially covering the semiconductor channel layer, a source electrode connected to the Dirac source layer, and a drain electrode connected to the semiconductor channel layer. The Dirac source layer may at least partially overlap the gate electrode in a vertical direction. The Dirac source layer may be spaced apart from the drain electrode. The Dirac source layer may not be connected to the drain electrode.

According to an embodiment of inventive concepts, a semiconductor device may include a substrate and a Dirac source transistor. The Dirac source transistor may include a gate electrode on the substrate; a gate dielectric film covering an upper surface of the gate electrode and side surfaces of the gate electrode; a semiconductor channel layer including a three-dimensional oxide semiconductor material, the semiconductor channel layer covering the upper surface of the gate electrode and the side surface of the gate electrode with the gate dielectric film therebetween; a Dirac source layer including a monolayer and partially covering the semiconductor channel layer; a source electrode spaced apart from the gate electrode in a horizontal direction and connected to the Dirac source layer; and a drain electrode spaced apart from the gate electrode in a direction opposite the horizontal direction, the drain electrode being on the semiconductor channel layer and connected to the semiconductor channel layer. The Dirac source layer may at least partially cover the upper surface of the gate electrode. The side surfaces of the gate electrode may include a side surface facing the source electrode and a side surface facing the drain electrode. The Dirac source layer may cover the side surface of the gate electrode facing the source electrode, and the Dirac source layer may not cover the side surface of the gate electrode facing the drain electrode.

According to an embodiment of inventive concepts a semiconductor device may include a substrate and a Dirac source transistor. The Dirac source transistor may include a gate electrode on the substrate; a gate dielectric film covering an upper surface of the gate electrode and side surfaces of the gate electrode; a semiconductor channel layer including a three-dimensional oxide semiconductor material, the semiconductor channel layer covering the upper surface of the gate electrode and the side surfaces of the gate electrode with the gate dielectric film therebetween; a Dirac source layer including a metallic or semi-metallic material having linear energy dispersion, the Dirac source layer partially covering the semiconductor channel layer and at least partially overlapping the gate electrode in a vertical direction; a source electrode spaced apart from the gate electrode in a horizontal direction, the source electrode above the semiconductor channel layer and the source electrode being connected to the Dirac source layer; and a drain electrode spaced apart from the gate electrode in a direction opposite the horizontal direction, the drain electrode being on the semiconductor channel layer and connected to the semiconductor channel layer. The semiconductor channel layer may extend from above the gate electrode to below the drain electrode and the semiconductor channel layer may be in contact with a lower surface of the drain electrode. The semiconductor channel layer may extend from above the gate electrode to below the source electrode. The Dirac source layer may extend between the source electrode and the semiconductor channel layer from above the gate electrode. A portion of the Dirac source layer may be in contact with a lower surface of the source electrode. The portion of the Dirac source layer may be between the lower surface of the source electrode and an upper surface of the semiconductor channel layer.

### BRIEF DESCRIPTION OF THE DRAWINGS

Embodiments will be more clearly understood from the following detailed description taken in conjunction with the accompanying drawings in which:

FIG. 1 is a cross-sectional view showing a semiconductor device according to embodiments;

FIGS. 2A to 2D, FIGS. 3A to 3C, and FIGS. 4A to 4C are cross-sectional views showing a method of manufacturing a semiconductor device, according to embodiments;

FIGS. 5A to 5C are cross-sectional views showing semiconductor devices according to embodiments;

FIG. 6 is a cross-sectional view showing a semiconductor device according to embodiments;

FIGS. 7A to 7C are cross-sectional views showing semiconductor devices according to embodiments;

FIGS. 8A and 8B are diagrams illustrating operation principles of a semiconductor device according to embodiments;

FIGS. 9A to 9C are diagrams illustrating operation characteristics of a semiconductor device according to embodiments; and

FIGS. 10A to 10C are diagrams illustrating operation characteristics of a semiconductor device according to embodiments.

### DETAILED DESCRIPTION OF THE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

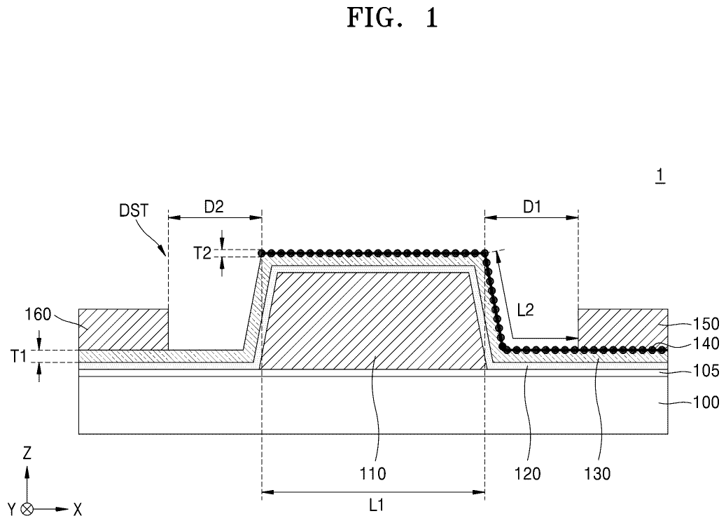

FIG. 1 is a cross-sectional view showing a semiconductor device 1 according to embodiments.

Referring to FIG. 1, the semiconductor device 1 includes a substrate 100, a gate electrode 110 above the substrate 100, a gate dielectric film 120 covering the gate electrode 110 above the substrate 100, a semiconductor channel layer 130 covering the gate dielectric film 120, a Dirac source layer 140 partially covering the semiconductor channel layer 130, a source electrode 150 connected to the Dirac source layer 140, and a drain electrode 160 connected to the semiconductor channel layer 130. The gate electrode 110, the gate dielectric film 120, the semiconductor channel layer 130, the Dirac source layer 140, the source electrode 150, and the drain electrode 160 may constitute a Dirac source transistor DST. The Dirac source transistor DST may include a field effect transistor (FET).

A Dirac source may be referred to as a cold source or cold electron source. For example, the Dirac source layer 140 may be referred to as a cold source layer or cold electron source layer, and the Dirac source transistor DST may be referred to as a cold source transistor or cold electron source transistor. The Dirac source transistor DST may be referred to as a Dirac source field effect transistor (DSFET), a cold source field effect transistor (CSFET), or a cold electron source field effect transistor (CESFET).

The substrate 100 may include semiconductor materials, such as Si and Ge, or compound semiconductor materials, such as SiGe, SiC, GaAs, InAs, and InP. The substrate 100 may include, for example, semiconductor materials, such as a group IV semiconductor material, a group III-V semiconductor material, and a group II-VI semiconductor material. The group IV semiconductor material may include, for example, silicon (Si), germanium (Ge), silicon-germanium (Si—Ge), or silicon carbide (SiC). The group III-V semiconductor material may include a binary, ternary, or quaternary compound containing at least one group III element and at least one group V element. The group III-V semiconductor material may include, for example, gallium arsenide (GaAs), indium arsenide (InAs), indium phosphide (InP), gallium phosphide (GaP), indium antimonide (InSb), or indium gallium arsenide (InGaAs). The group II-VI semiconductor material may include, for example, zinc telluride (ZnTe) or cadmium sulfide (CdS). In some embodiments, the substrate 100 may include a bulk wafer or an epitaxial layer. In some other embodiments, the substrate 100 may include a silicon-on-insulator (SOI) substrate or a germanium-on-insulator (GeOI) substrate. The substrate 100 may include a conductive region, for example, wells doped with impurities. In some embodiments, at least an upper portion of the substrate 100 may include a p+ region excessively doped with p-type impurities. The substrate 100 may have various device isolation structures, such as a shallow trench isolation (STI) structure.

The gate electrode 110 may be formed on the substrate 100. In some embodiments, the gate electrode 110 may be formed by forming a conductive material layer on the substrate 100 and then patterning the conductive material layer through a photolithography process and/or a lift-off process. The gate electrode 110 may include a doped semiconductor material, such as doped polysilicon, a metal, a conductive metal nitride, a conductive metal oxide, a conductive metal silicide, or a combination thereof. In some embodiments, the gate electrode 110 may include a conductive barrier film and a conductive filling layer covering the conductive barrier film. For example, the conductive barrier film may include Ti, TiN, Ta, TaN, or a combination thereof. For example, the conductive filling layer may include doped silicon, Al, Cu, Cr, Au, W, Ru, Pt, Ir, Ti, W, Ta, TiN, WN, TaN, TiAlN, TiSiN, TaAlN, TaSiN, RuO, PtO, IrO, SRO(SrRuO), BSRO((Ba,Sr)RuO), CRO(CaRuO), BaRuO, La(Sr,Co)O, or a combination thereof.

In some embodiments, the gate electrode 110 may include a stack structure of Au and Cr. For example, the gate electrode 110 may have a thickness of several tens of nm. For example, the gate electrode 110 may have a thickness of about 30 nm to about 70 nm. In some embodiments, the gate electrode 110 may include a stack structure of Au having a thickness of about 45 nm and Cr having a thickness of about 5 nm. In some embodiments, the gate width of the gate electrode 110 may be greater than the gate length thereof. For example, the gate electrode 110 may have a gate width that is about 2 to about 6 times greater than the gate length. In some embodiments, when the gate electrode 110 has a gate length of several tens of nm in a first horizontal direction (an X direction), for example, about 20 nm to about 60 nm, the gate electrode 110 may have a gate width of about 100 nm to about 300 nm in a second horizontal direction (a Y direction). In some embodiments, when the gate electrode 110 has a gate length of several tens of μm in the first horizontal direction (the X direction), for example, about 20 μm to about 60 μm, the gate electrode 110 may have a gate width of about 100 μm to about 300 μm in the second horizontal direction (the Y direction). The first horizontal direction (the X direction) and the second horizontal direction (the Y direction) may be perpendicular to each other.

In some embodiments, a base insulating layer 105 may be disposed on the substrate 100. For example, the base insulating layer 105 may be located between the substrate 100 and the gate electrode 110. The base insulating layer 105 may include an insulating material. The base insulating layer 105 may include, for example, silicon oxide. The base insulating layer 105 may have a thickness of several tens of nm. For example, the base insulating layer 105 may have a thickness of about 10 nm to about 80 nm.

The gate dielectric film 120 may cover the gate electrode 110 above the substrate 100. In some embodiments, the gate dielectric film 120 may cover the upper surface of the base insulating layer 105 and the upper surface and side surfaces of the gate electrode 110. The gate dielectric film 120 may have a thickness of about 5 nm to about 15 nm. The gate dielectric film 120 may include at least one selected from a group consisting of silicon oxide, a high-k dielectric material having a higher dielectric constant than silicon oxide, and a ferroelectric material. In some embodiments, the gate dielectric film 120 may include a stack structure of an interface film (or an interface layer) and a high-k dielectric film. For example, the interface layer may include silicon oxide. In some embodiments, the interface layer may be omitted. The high-k dielectric film may include a material having a higher dielectric constant than the silicon oxide film. For example, the high dielectric film may include at least one selected from a group consisting of a high-k dielectric material and a ferroelectric material having a dielectric constant of about 10 to about 25. For example, the high-k dielectric material and the ferroelectric material may include at least one selected from a group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

In some embodiments, the gate dielectric film 120 may include a ferroelectric material film having ferroelectric characteristics and a paraelectric material film having paraelectric characteristics. The ferroelectric material may have negative capacitance and the paraelectric material film may have positive capacitance. For example, when two or more capacitors are connected to each other in series, and the capacitance of each capacitor has a positive value, the total capacitance is less than the capacitance of each individual capacitor. On the other hand, when at least one of the capacitances of two or more capacitors connected to each other in series has a negative value, the total capacitance may be positive and greater than the absolute value of each individual capacitance.

When a ferroelectric material film having negative capacitance is connected in series to a paraelectric material film having positive capacitance, the total capacitance value of the ferroelectric material film and the paraelectric material film connected to each other in series may increase. Using the characteristic that the total capacitance value increases as described above, a transistor including the ferroelectric material film may have a subthreshold swing of less than 60 m V/decade at room temperature.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Herein, for example, the hafnium zirconium oxide may include the hafnium oxide doped with zirconium (Zr). In another example, the hafnium zirconium oxide may include a compound of hafnium (Hf), zirconium (Zr), and oxygen (O).

The ferroelectric material film may further include a dopant doping the same. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on what kind of ferroelectric material the ferroelectric material film contains, the type of dopant in the ferroelectric material film may vary.

When the ferroelectric material film contains hafnium oxide, the dopant in the ferroelectric material film may include, for example, at least one of gadolinium (Gd), silicon (Si), zirconium (Zr), aluminum (Al), and yttrium (Y).

When the dopant includes aluminum (Al), the ferroelectric material film may contain about 3 at % (atomic %) to about 8 at % of aluminum. Herein, the ratio of the dopant may represent the ratio of aluminum to the sum of hafnium and aluminum.

When the dopant includes silicon (Si), the ferroelectric material film may contain about 2 at % to about 10 at % of silicon. When the dopant includes yttrium (Y), the ferroelectric material film may contain about 2 at % to about 10 at % of yttrium. When the dopant includes gadolinium (Gd), the ferroelectric material film may contain 1 at % to about 7 at % of gadolinium. When the dopant includes zirconium (Zr), the ferroelectric material film may contain about 50 at % to about 80 at % of zirconium.

The paraelectric material film may have the paraelectric characteristics. The paraelectric material film may include, for example, at least one of silicon oxide and metal oxide having a high dielectric constant. The metal oxide in the paraelectric material film may include, for example, at least one of hafnium oxide, zirconium oxide, and aluminum oxide, but the embodiment is not limited thereto.

The ferroelectric material film and the paraelectric material film may include the same material. The ferroelectric material film may have ferroelectric characteristics, but the paraelectric material film may not have ferroelectric characteristics. For example, when the ferroelectric material film and the paraelectric material film include hafnium oxide, the crystal structure of hafnium oxide in the ferroelectric material film is different from the crystal structure of hafnium oxide in the paraelectric material film.

The ferroelectric material film may have a thickness exhibiting the ferroelectric characteristics. The thickness of the ferroelectric material film may be, for example, about 0.5 nm to about 10 nm, but the embodiments are not limited thereto. Since the critical thickness of the ferroelectric material that exhibits the ferroelectric characteristics may vary for each ferroelectric material, the thickness of the ferroelectric material film may vary depending on the ferroelectric material.

In some embodiments, the gate dielectric film 120 may include a single ferroelectric material film. In some embodiments, the gate dielectric film 120 may include a plurality of ferroelectric material films spaced apart from each other. The gate dielectric film 120 may have a stacked film structure in which a plurality of ferroelectric material films and a plurality of paraelectric material films are alternately stacked on each other.

FIG. 1 illustrates that the gate dielectric film 120 extends from between the semiconductor channel layer 130 and the gate electrode 110 to between the semiconductor channel layer 130 and the base insulating layer 105, but the embodiment is not limited thereto. In some embodiments, the gate dielectric film 120 may be located in the entire regions between the semiconductor channel layer 130 and the gate electrode 110 but may not be located in at least some regions between the semiconductor channel layer 130 and the base insulating layer 105. In some embodiments, in an X-Z plane formed by the first horizontal direction (the X direction) and a vertical direction (a Z direction), the gate electrode 110 may be completely surrounded by the base insulating layer 105 and the gate dielectric film 120. For example, the base insulating layer 105 may cover the lower surface of the gate electrode 110, and the gate dielectric film 120 may cover the side surfaces and upper surface of the gate electrode 110.

The semiconductor channel layer 130 may cover the gate dielectric film 120. The semiconductor channel layer 130 may cover the side surfaces and the upper surface of the gate electrode 110 with the gate dielectric film 120 therebetween. The semiconductor channel layer 130 may include an oxide semiconductor material. In some embodiments, the semiconductor channel layer 130 may be doped with n-type impurities, but the embodiment is not limited thereto. For example, the semiconductor channel layer 130 may be doped with either n-type impurities or p-type impurities. The semiconductor channel layer 130 may have a first thickness T1. In some embodiments, the semiconductor channel layer 130 may include a three-dimensional oxide semiconductor material. For example, the first thickness T1 of the semiconductor channel layer 130 may be 10 nm or more so that the semiconductor channel layer 130 includes an oxide semiconductor material having a three-dimensional structure. In some embodiments, the first thickness T1 of the semiconductor channel layer 130 may be about 10 nm to about 30 nm.

The semiconductor channel layer 130 may extend from above the gate electrode 110 below the drain electrode 160 and be in contact with the lower surface of the drain electrode 160 and may also extend from above the gate electrode 110 to below the source electrode 150. A portion of the Dirac source layer 140 in contact with the lower surface of the source electrode 150 may be located between the lower surface of the source electrode 150 and the upper surface of the semiconductor channel layer 130.

The oxide semiconductor material may include mono-metal oxide semiconductor materials, multi-element metal oxide semiconductor materials of metal elements and oxygen, multi-element metal oxide semiconductor materials in which elements, such as Hf, Zr, Al, Sr, and Si, act as doping elements, or a combination thereof. For example, the oxide semiconductor material may include InOₓ, GaOₓ, ZnOₓ, SnOₓ, CuOₓ, TiOₓ, NiOₓ, VOₓ, InₓGa_{y}O, InₓZn_{y}O, InₓGa_{y}Zn₂O, InₓGa_{y}Si_{z}O, InₓSn_{y}Zn_{z}O, ZnₓO, ZnₓSn_{y}O, ZnₓO_{y}N, ZrₓZn_{y}Sn₂O, SnₓO, HfₓIn_{y}Zn_{z}O, GaₓZn_{y}Sn_{z}O, AlₓZn_{y}Sn_{z}O, YbₓGa_{y}Zn_{z}O, or a combination thereof.

In some embodiments, the semiconductor channel layer 130 may include a single layer or multi layers of the oxide semiconductor material. In some embodiments, the semiconductor channel layer 130 may include a material having band gap energy greater than that of silicon. For example, the semiconductor channel layer 130 may include a material having a band gap energy of about 1.5 eV to about 5.6 eV. For example, the semiconductor channel layer 130 may include a material that may exhibit optimal channel performance when having a band gap energy of about 2.0 eV to about 4.0 eV.

The Dirac source layer 140 may partially cover the semiconductor channel layer 130. The Dirac source layer 140 may have a second thickness T2. The second thickness T2 of the Dirac source layer 140 may be less than the first thickness T1 of the semiconductor channel layer 130. For example, the second thickness T2 of the Dirac source layer 140 may be about 3 Å to about 7 Å. In some embodiments, the Dirac source layer 140 may be doped with impurities of a different conductivity type than the semiconductor channel layer 130. For example, when the semiconductor channel layer 130 is doped with n-type impurities, the Dirac source layer 140 may be doped with p-type impurities. Also, when the semiconductor channel layer 130 is doped with p-type impurities, the Dirac source layer 140 may be doped with n-type impurities. The semiconductor channel layer 130 may have the first thickness T1. In some embodiments, the semiconductor channel layer 130 may include the three-dimensional oxide semiconductor material.

The Dirac source layer 140 may at least partially overlap the gate electrode 110 in the vertical direction (the Z direction). In some embodiments, the Dirac source layer 140 may completely overlap the gate electrode 110 in the vertical direction (the Z direction). In the first horizontal direction (the X direction), the Dirac source layer 140 may extend from above the gate electrode 110 toward the source electrode 150. The Dirac source layer 140 may be in contact with the semiconductor channel layer 130 above the gate electrode 110. Also, the Dirac source layer 140 may extend from above the gate electrode 110 toward the source electrode 150 and be in contact with the source electrode 150. The Dirac source layer 140 may extend between the semiconductor channel layer 130 and the source electrode 150.

The Dirac source layer 140 may cover a portion of the semiconductor channel layer 130 that covers the upper surface of the gate electrode 110, but may not cover another portion of the semiconductor channel layer 130 that covers the side surface of the gate electrode 110 facing the drain electrode 160 in the first horizontal direction (the X direction). The Dirac source layer 140 may be spaced apart from the drain electrode 160 and thus not connected thereto. In some embodiments, the Dirac source layer 140 may not extend from above the gate electrode 110 toward the drain electrode 160 in the first horizontal direction (the X direction). For example, one end of the Dirac source layer 140 facing the drain electrode 160 in the first horizontal direction (the X direction) may be aligned with one end of the gate electrode 110 in the vertical direction (the Z direction).

In the X-Z plane, a portion of the Dirac source layer 140 that overlaps the gate electrode 110 in the vertical direction (the Z direction) may extend with a first length L1, and another portion of the Dirac source layer 140 that extends from the portion thereof overlapping the gate electrode 110 in the vertical direction to the source electrode 150 may extend with a second length L2. The portion of the Dirac source layer 140 that overlaps the gate electrode 110 in the vertical direction (the Z direction) may be referred to as the first portion of the Dirac source layer 140. Also, the portion of the Dirac source layer 140 that extends from the first portion of the Dirac source layer 140 toward the source electrode 150 may be referred to as the second portion of the Dirac source layer 140. For example, the second portion of the Dirac source layer 140 may extend having the second length L2 while covering the upper surface of a portion of the semiconductor channel layer 130 covering the side surface of the gate electrode 110 facing the source electrode 150 in the first horizontal direction (the X direction) and the upper surface of another portion of the semiconductor channel layer 130 located between the gate electrode 110 and the source electrode 150. The first length L1 of the Dirac source layer 140 may be greater than the second length L2 of the Dirac source layer 140. The first length L1 of the Dirac source layer 140 may be substantially equal to the gate length of the gate electrode 110.

The Dirac source layer 140 may include metallic or semi-metallic materials having linear energy dispersion. For example, the Dirac source layer 140 may include semi-metallic materials, such as graphene, Te, and Cd₃C₂, and two-dimensional transition metal chalcogenide compounds having metallic or semi-metallic characteristics, such as NbS₂, NbSe₂, NbTe₂, TaS₂, TaSc₂, TaTe₂, and VTe₂. The Dirac source layer 140 may include a monolayer. For example, when the Dirac source layer 140 includes graphene, the second thickness T2 of the Dirac source layer 140 may be about 4 Å.

The source electrode 150 may be located on one side in the first horizontal direction (the X direction) from the gate electrode 110, and the drain electrode 160 may be located on the other side in the first horizontal direction (the X direction) therefrom. Each of the source electrode 150 and the drain electrode 160 may include doped semiconductor materials, such as doped polysilicon, metal, conductive metal nitride, conductive metal oxide, conductive metal silicide, or a combination thereof. The source electrode 150 and the drain electrode 160 may include the same material. In some embodiments, each of the source electrode 150 and the drain electrode 160 may include the same material as the gate electrode 110, but the embodiment is not limited thereto.

Each of the source electrode 150 and the drain electrode 160 may be spaced apart from the gate electrode 110 in the first horizontal direction (the X direction). For example, in the first horizontal direction (the X direction), the gate electrode 110 and the source electrode 150 may be spaced apart from each other by a first distance D1, and the gate electrode 110 and the drain electrode 160 may be spaced apart from each other by a second distance D2 that is greater than the first distance D1. The source electrode 150 may be spaced apart from an effective gate length of the gate electrode 110. The first distance D1 may be greater than 0 but less than the second length L2 of the Dirac source layer 140.

The semiconductor device 1 according to inventive concepts may include a Dirac source transistor DST that is constituted by the gate electrode 110, the gate dielectric film 120, the semiconductor channel layer 130, the Dirac source layer 140, the source electrode 150, and the drain electrode 160.

The Dirac source layer 140 at least partially overlaps the gate electrode 110 in the vertical direction (the Z direction) and may thus adjust the energy barrier between the semiconductor channel layer 130 and the Dirac source layer 140. Accordingly, the Dirac source transistor DST may provide lower subthreshold swing values and/or higher on-current.

In addition, since the source electrode 150 is located closer to the gate electrode 110 than the drain electrode 160, the resistance component of the Dirac source layer 140 is reduced. Accordingly, the Dirac source transistor DST may provide higher on-current. The Dirac source layer 140 does not extend from the gate electrode 110 toward the drain electrode 160, and the drain electrode 160 is located farther from the gate electrode 110 than the source electrode 150. Accordingly, when the Dirac source transistor DST is turned off, leakage current may be limited and/or prevented from occurring between the Dirac source layer 140 and the drain electrode 160. As a result, the Dirac source transistor DST may provide lower off-current.

Therefore, the Dirac source transistor DST in the semiconductor device 1 according to inventive concepts provides the lower subthreshold swing value, the higher on-current, and the lower off-current, and thus, the power consumption in the semiconductor device 1 may be reduced.

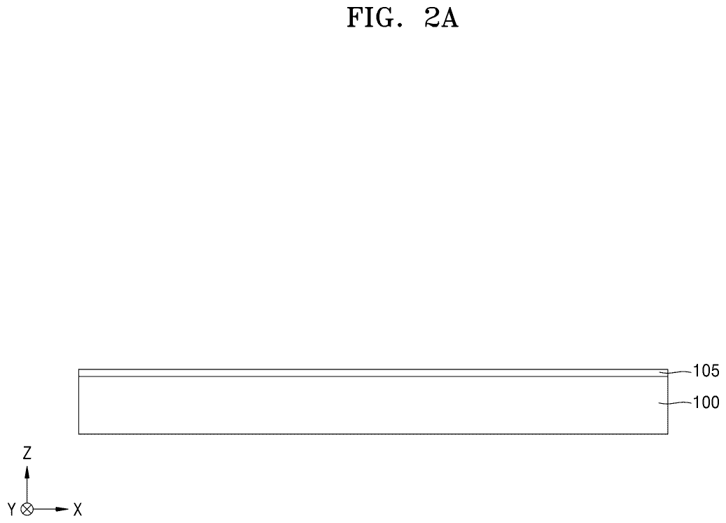

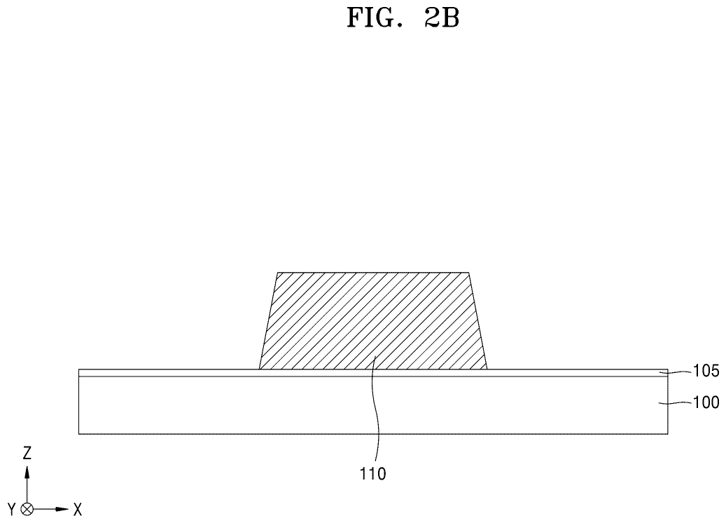

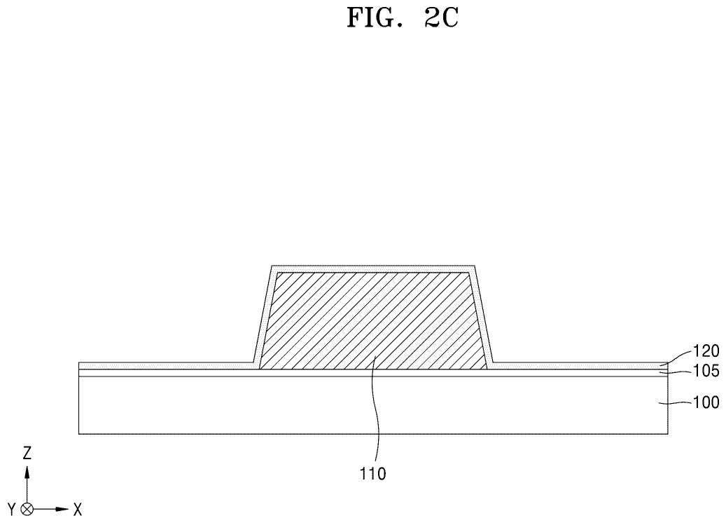

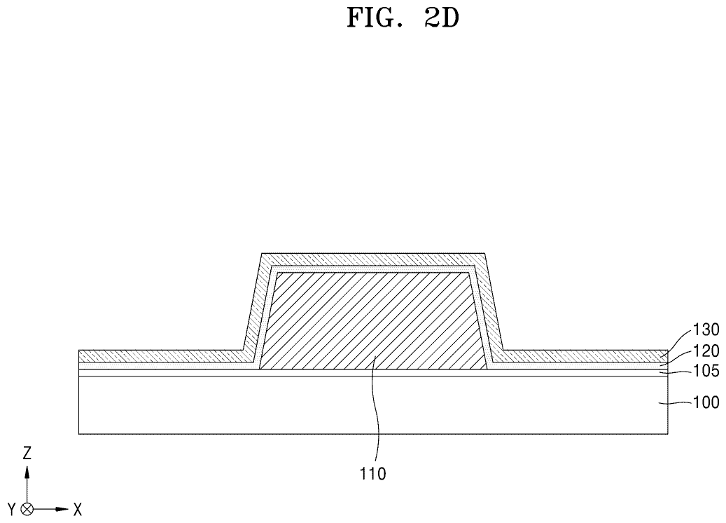

FIGS. 2A to 2D, FIGS. 3A to 3C, and FIGS. 4A to 4C are cross-sectional views showing a method of manufacturing a semiconductor device, according to embodiments.

Referring to FIG. 2A, a base insulating layer 105 is formed on a substrate 100. The substrate 100 may include semiconductor materials, such as Si and Ge, or compound semiconductor materials, such as SiGe, SiC, GaAs, InAs, and InP. In some embodiments, a p+ region excessively doped with p-type impurities may be formed in at least an upper portion of the substrate 100. The base insulating layer 105 may be formed on the substrate 100 by a deposition process or an oxidation process. The base insulating layer 105 may include, for example, silicon oxide. The base insulating layer 105 may have a thickness of several tens of nm.

Referring to FIG. 2B, a gate electrode 110 may be formed by forming a conductive material layer above the substrate 100, on which the base insulating layer 105 is formed, and then patterning the conductive material layer through a photolithography process and/or a lift-off process. The gate electrode 110 may include a doped semiconductor material, such as doped polysilicon, a metal, a conductive metal nitride, a conductive metal oxide, a conductive metal silicide, or a combination thereof. In some embodiments, the gate electrode 110 may include a stack structure of Au and Cr.

Referring to FIG. 2C, a gate dielectric film 120 is formed above the substrate 100 so as to cover the gate electrode 110. For example, the gate dielectric film 120 may have a thickness of about 5 nm to about 15 nm. In some embodiments, the gate dielectric film 120 may be formed using an atomic layer deposition (ALD) process. The gate dielectric film 120 may include at least one selected from a group consisting of silicon oxide, a high-k dielectric material having a higher dielectric constant than silicon oxide, and a ferroelectric material. In some embodiments, when the gate dielectric film 120 includes Al₂O₃ or HfO₂, the gate dielectric film 120 may be formed by the ALD process that uses trimethylaluminum (TMA) or Tetrakis(ethylmethylamino)Hf (TEMAHf) as a precursor and uses H₂O or ozone (O₃) as an oxidizing agent.

In some embodiments, after the gate dielectric film 120 is formed, unnecessary portions of the gate dielectric film 120 may be removed. For example, those portions of the gate dielectric film 120 may be removed through a photolithography process and a wet etching process. In some embodiments, when the gate dielectric film 120 includes Al₂O₃ or HfO₂, the portions of the gate dielectric film 120 may be removed using phosphoric acid (H₃PO₄) or buffered oxide etchant (10:1) as an etchant.

Referring to FIG. 2D, a semiconductor channel layer 130 is formed so as to cover the gate dielectric film 120. The semiconductor channel layer 130 may cover the side surfaces and the upper surface of the gate electrode 110 with the gate dielectric film 120 therebetween. The semiconductor channel layer 130 may include an oxide semiconductor material. The semiconductor channel layer 130 may be doped with impurities having a first conductivity type. In some embodiments, the first conductivity type may include, but not limited to, an n type. For example, the first conductivity type may include a p type. The semiconductor channel layer 130 may include an oxide semiconductor material. In some embodiments, the semiconductor channel layer 130 may include a three-dimensional oxide semiconductor material. For example, the semiconductor channel layer 130 may have a thickness of 10 nm or more.

The semiconductor channel layer 130 may be formed by a sol-gel process, a chemical vapor deposition (CVD) process, or an ALD process. For example, the semiconductor channel layer 130 may include InₓGa_{y}Zn_{z}O formed by the sol-gel process. For example, UV-ozone treatment is performed on the substrate 100, above which the gate dielectric film 120 is formed, and a coating solution is applied on the substrate 100, above which the gate dielectric film 120 is formed by spin-coating, and then heat-treated. Through the above processes, the semiconductor channel layer 130 may be formed by the sol-gel process. The heat treatment may include primary heat treatment performed at 70° C. and secondary heat treatment performed at 350° C. When the semiconductor channel layer 130 includes InₓGa_{y}Zn_{z}O, the coating solution may use indium nitrate hydrate, gallium nitrate hydrate, and zinc nitrate as precursors. For example, indium nitrate hydrate, gallium nitrate hydrate, and zinc nitrate may be added to 2-methoxyethanol and then mixed under temperature conditions to form the coating solution. In some embodiments, the coating solution may be formed by a mixing process for 24 hours at a temperature of 60° C.

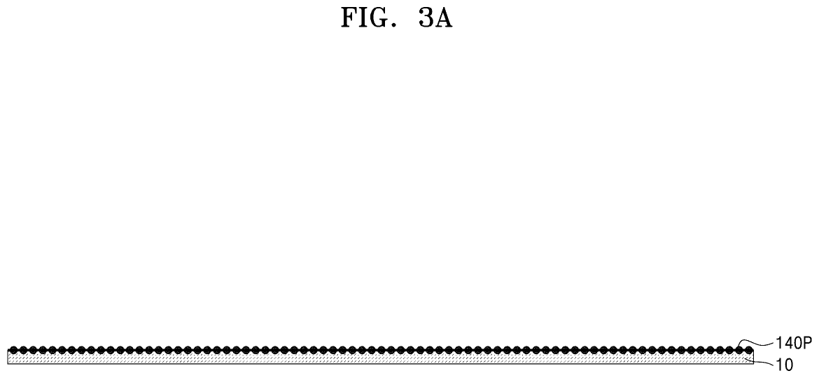

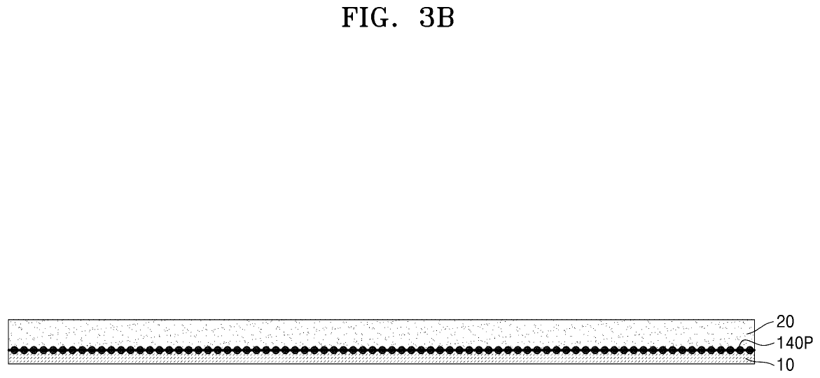

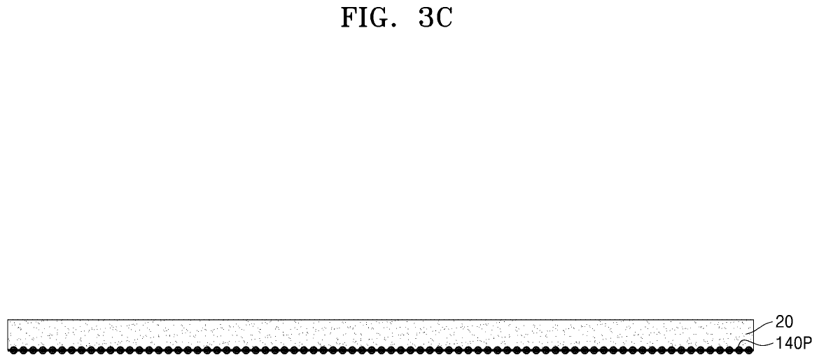

Referring to FIG. 3A, a base support layer 10 is provided, on which a preliminary Dirac source layer 140P is formed. For example, the base support layer 10 may include copper (Cu) foil. The preliminary Dirac source layer 140P may include a monolayer that includes metallic or semi-metallic materials having linear energy dispersion. In some embodiments, the preliminary Dirac source layer 140P may include a single layer of graphene.

Referring to FIG. 3B, a fixing layer 20 is formed on the preliminary Dirac source layer 140P. In some embodiments, the fixing layer 20 may include polymethyl methacrylate (PMMA). For example, the fixing layer 20 may be formed, by spin coating, above the base support layer 10 on which the preliminary Dirac source layer 140P is formed.

Referring to FIGS. 3B and 3C together, the base support layer 10 is removed. For example, when the base support layer 10 includes a Cu foil, the base support layer 10 may be removed using a ferric chloride solution. After the base support layer 10 is removed, the stack structure of the fixing layer 20 and the preliminary Dirac source layer 140P may be immersed in deionized water (DI) water.

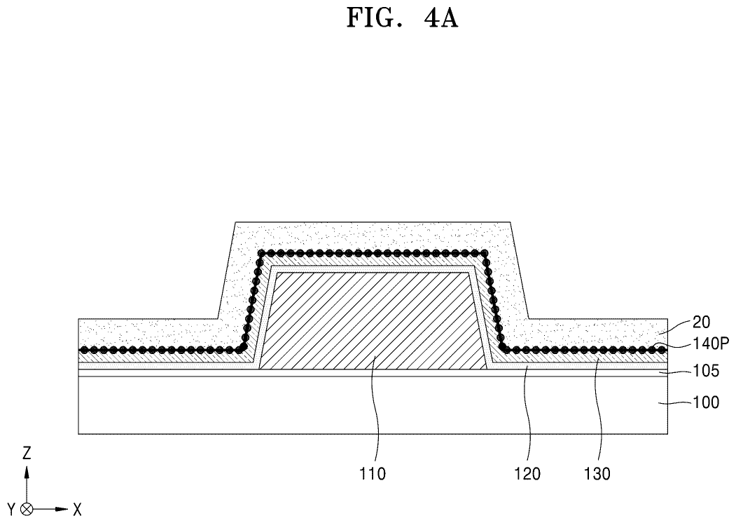

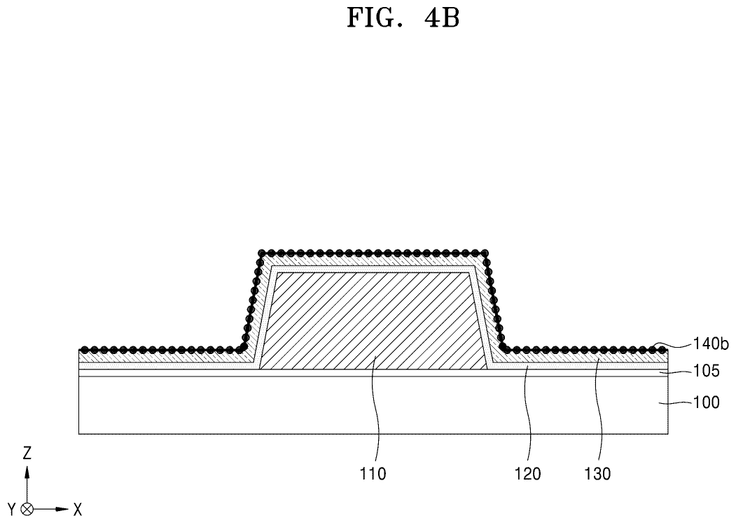

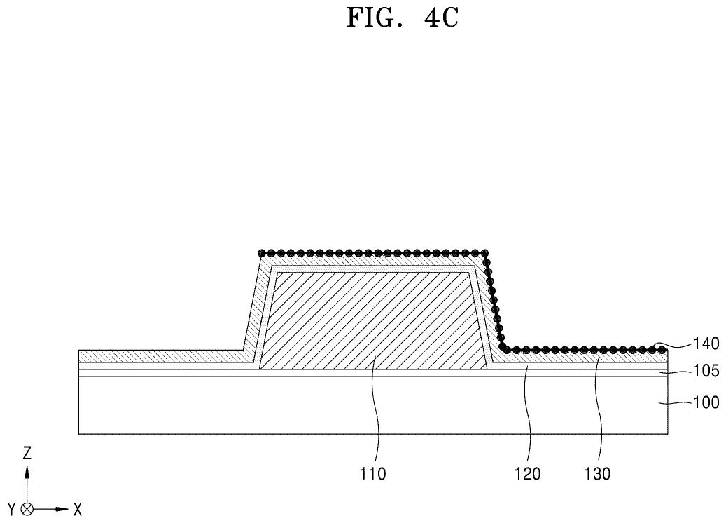

Referring to FIG. 4A, the stack structure of the fixing layer 20 and the preliminary Dirac source layer 140P shown in FIG. 3C is transferred onto the semiconductor channel layer 130. The stack structure of the fixing layer 20 and the preliminary Dirac source layer 140P may be transferred onto the semiconductor channel layer 130 such that the preliminary Dirac source layer 140P is brought into contact with the upper surface of the semiconductor channel layer 130. Subsequently, a drying process may be performed on the resultant structure. For example, the drying process may be performed in an atmosphere with a temperature of 50° C.

Referring to FIGS. 4A and 4B together, the fixing layer 20 is removed. When the fixing layer 20 includes PMMA, the fixing layer 20 may be removed using acetone. The preliminary Dirac source layer 140P remaining after the fixing layer 20 is removed may cover the upper surface of the semiconductor channel layer 130.

FIGS. 3A to 4B illustrate a method of forming the preliminary Dirac source layer 140P on the semiconductor channel layer 130 using the fixing layer 20, for example, a PMMA-assisted transfer method, but the method of forming the preliminary Dirac source layer 140P on the semiconductor channel layer 130 is not limited thereto. In some embodiments, the preliminary Dirac source layer 140P may be formed directly on the semiconductor channel layer 130.

Referring to FIGS. 4B and 4C together, the preliminary Dirac source layer 140P is partially removed to form the Dirac source layer 140. For example, the Dirac source layer 140 may be formed by patterning the preliminary Dirac source layer 140P by a photolithography process and a dry etching process. In some embodiments, the Dirac source layer 140 may be formed by the dry etching process that is performed on the preliminary Dirac source layer 140P by using Ar+O₂ as an etching gas.

In some embodiments, the Dirac source layer 140 may not be doped with impurities, but example embodiments are not limited thereto. In some embodiments, the Dirac source layer 140 may be doped with impurities having a second conductivity type different from the first conductivity type. In some embodiments, the first conductivity type may include the n type and the second conductivity type may include the p type, but the embodiment is not limited thereto. For example, the first conductivity type may include the p type and the second conductivity type may include the n type. In some embodiments, the preliminary Dirac source layer 140P shown in FIG. 3A may be doped with impurities having the second conductivity type. In some embodiments, the preliminary Dirac source layer 140P remaining after the fixing layer 20 shown in FIGS. 4A and 4B is removed may be doped with impurities having the second conductivity type. In some embodiments, the Dirac source layer 140, which is formed by partially removing the preliminary Dirac source layer 140P of FIGS. 4B and 4C, may be doped with impurities having the second conductivity type.

Subsequently, the semiconductor device 1 may be formed by forming the source electrode 150 and the drain electrode 160 shown in FIG. 1. A conductive material layer is formed, which includes a doped semiconductor material, such as doped polysilicon, a metal, a conductive metal nitride, a conductive metal oxide, a conductive metal silicide, or a combination thereof. Then, each of the source electrode 150 and the drain electrode 160 may be formed by patterning the conductive material layer through a photolithography process and/or a lift-off process.

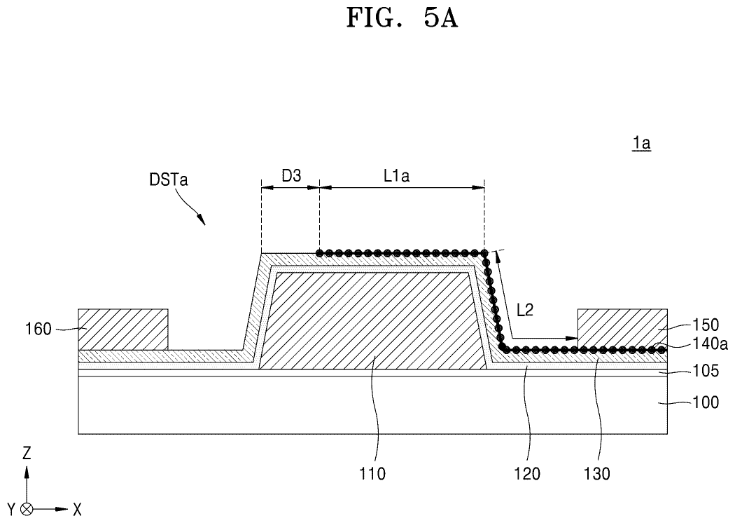

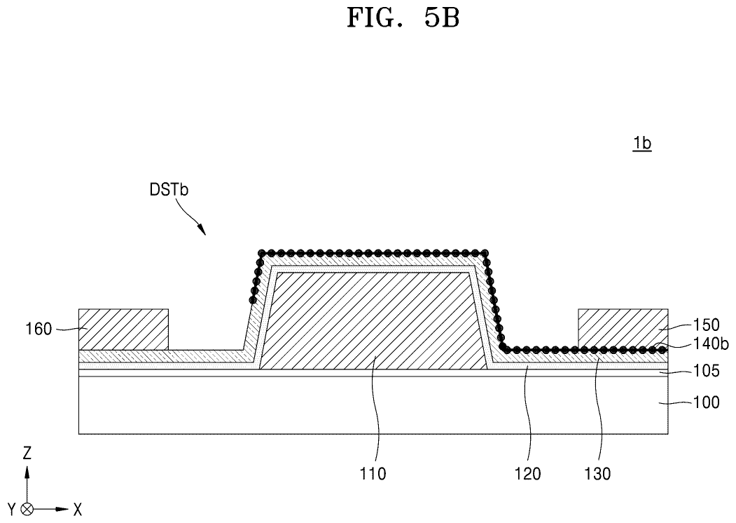

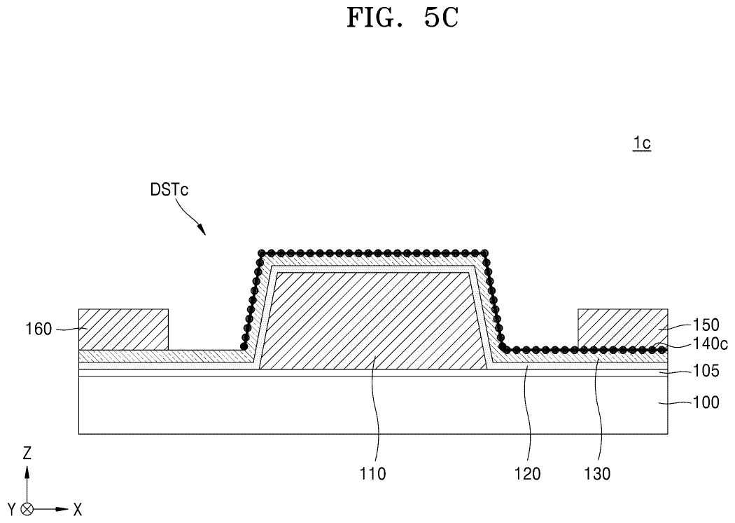

FIGS. 5A to 5C are cross-sectional views showing semiconductor devices according to embodiments.

Referring to FIG. 5A, a semiconductor device 1a includes a substrate 100, a gate electrode 110 above the substrate 100, a gate dielectric film 120 covering the gate electrode 110 above the substrate 100, a semiconductor channel layer 130 covering the gate dielectric film 120, a Dirac source layer 140a partially covering the semiconductor channel layer 130, a source electrode 150 connected to the Dirac source layer 140a, and a drain electrode 160 connected to the semiconductor channel layer 130. The gate electrode 110, the gate dielectric film 120, the semiconductor channel layer 130, the Dirac source layer 140a, the source electrode 150, and the drain electrode 160 may constitute a Dirac source transistor DSTa. The Dirac source transistor DSTa may include an FET. In some embodiments, a base insulating layer 105 may be disposed on the substrate 100. For example, the base insulating layer 105 may be located between the substrate 100 and the gate electrode 110.

The semiconductor channel layer 130 may cover the side surfaces and the upper surface of the gate electrode 110 with the gate dielectric film 120 therebetween. The Dirac source layer 140a may partially cover the semiconductor channel layer 130. The Dirac source layer 140a may overlap a portion of the gate electrode 110 in a vertical direction (a Z direction) but may not overlap the remaining portion thereof in the vertical direction (the Z direction). For example, the Dirac source layer 140a may overlap, in the vertical direction (the Z direction), a portion of the gate electrode 110 adjacent to the source electrode 150 but may not overlap, in the vertical direction (the Z direction), the remaining portion of the gate electrode 110 adjacent to the drain electrode 160.

In a first horizontal direction (an X direction), the Dirac source layer 140a may extend from above the gate electrode 110 toward the source electrode 150. The Dirac source layer 140a may be in contact with the semiconductor channel layer 130 above the gate electrode 110. Also, the Dirac source layer 140a may extend from above the gate electrode 110 toward the source electrode 150 and be in contact with the source electrode 150.

In an X-Z plane, a first portion of the Dirac source layer 140a that overlaps the gate electrode 110 in the vertical direction (the Z direction) may extend with a first length L1a, and a second portion of the Dirac source layer 140a that extends from the first portion thereof to the source electrode 150 may extend with a second length L2. The first length L1a of the Dirac source layer 140a may be greater than the second length L2 of the Dirac source layer 140a. The first length L1a of the Dirac source layer 140a may be less the gate length of the gate electrode 110. One end of the Dirac source layer 140a facing the drain electrode 160 may be spaced apart from one end of the gate electrode 110 by a third distance D3 in the first horizontal direction (the X direction). The third distance D3 may be less than the first length L1a of the Dirac source layer 140a.

Referring to FIG. 5B, a semiconductor device 1b includes a substrate 100, a gate electrode 110 above the substrate 100, a gate dielectric film 120 covering the gate electrode 110 above the substrate 100, a semiconductor channel layer 130 covering the gate dielectric film 120, a Dirac source layer 140b partially covering the semiconductor channel layer 130, a source electrode 150 connected to the Dirac source layer 140b, and a drain electrode 160 connected to the semiconductor channel layer 130. The gate electrode 110, the gate dielectric film 120, the semiconductor channel layer 130, the Dirac source layer 140b, the source electrode 150, and the drain electrode 160 may constitute a Dirac source transistor DSTb. The Dirac source transistor DSTb may include an FET. In some embodiments, a base insulating layer 105 may be disposed on the substrate 100. For example, the base insulating layer 105 may be located between the substrate 100 and the gate electrode 110.

The semiconductor channel layer 130 may cover the side surfaces and the upper surface of the gate electrode 110 with the gate dielectric film 120 therebetween. The Dirac source layer 140b may partially cover the semiconductor channel layer 130. The Dirac source layer 140b may completely overlap the gate electrode 110 in a vertical direction (a Z direction). For example, the Dirac source layer 140b may extend from above the gate electrode 110 toward the drain electrode 160 in a first horizontal direction (an X direction). The Dirac source layer 140b may entirely cover the semiconductor channel layer 130 covering the upper surface of the gate electrode 110 and entirely cover the semiconductor channel layer 130 covering the side surface of the gate electrode 110 facing the source electrode 150 in the first horizontal direction (the X direction). Also, the Dirac source layer 140b may cover a portion of the semiconductor channel layer 130 covering the upper portion of the side surface of the gate electrode 110 facing the drain electrode 160 in the first horizontal direction (the X direction) but may not cover another portion of the semiconductor channel layer 130 covering the lower portion of the side surface of the gate electrode 110 facing the drain electrode 160 in the first horizontal direction (the X direction). A portion of the semiconductor channel layer 130, which is located between the drain electrode 160 and the portion of the semiconductor channel layer 130 covering the upper surface and the side surface of the gate electrode 110, may be not covered by the Dirac source layer 140b. Another portion of the semiconductor channel layer 130, which is located between the source electrode 150 and the portion of the semiconductor channel layer 130 covering the upper surface and the side surface of the gate electrode 110, may be covered by the Dirac source layer 140b.

Referring to FIG. 5C, a semiconductor device 1c includes a substrate 100, a gate electrode 110 above the substrate 100, a gate dielectric film 120 covering the gate electrode 110 above the substrate 100, a semiconductor channel layer 130 covering the gate dielectric film 120, a Dirac source layer 140c partially covering the semiconductor channel layer 130, a source electrode 150 connected to the Dirac source layer 140c, and a drain electrode 160 connected to the semiconductor channel layer 130. The gate electrode 110, the gate dielectric film 120, the semiconductor channel layer 130, the Dirac source layer 140c, the source electrode 150, and the drain electrode 160 may constitute a Dirac source transistor DSTc. The Dirac source transistor DSTc may include an FET. In some embodiments, a base insulating layer 105 may be disposed on the substrate 100. For example, the base insulating layer 105 may be located between the substrate 100 and the gate electrode 110.

The semiconductor channel layer 130 may cover the side surfaces and the upper surface of the gate electrode 110 with the gate dielectric film 120 therebetween. The Dirac source layer 140c may partially cover the semiconductor channel layer 130. The Dirac source layer 140c may completely overlap the gate electrode 110 in a vertical direction (a Z direction). For example, the Dirac source layer 140c may extend from above the gate electrode 110 toward the drain electrode 160 in a first horizontal direction (an X direction). The Dirac source layer 140c may entirely cover the semiconductor channel layer 130 covering the upper surface of the gate electrode 110, entirely cover the semiconductor channel layer 130 covering the side surface of the gate electrode 110 facing the source electrode 150 in the first horizontal direction (the X direction), and entirely cover the semiconductor channel layer 130 covering the side surface of the gate electrode 110 facing the drain electrode 160 in the first horizontal direction (the X direction). A portion of the semiconductor channel layer 130, which is located between the drain electrode 160 and the portion of the semiconductor channel layer 130 covering the upper surface and the side surface of the gate electrode 110, may be not covered by the Dirac source layer 140c. Another portion of the semiconductor channel layer 130, which is located between the source electrode 150 and the portion of the semiconductor channel layer 130 covering the upper surface and the side surface of the gate electrode 110, may be covered by the Dirac source layer 140c.

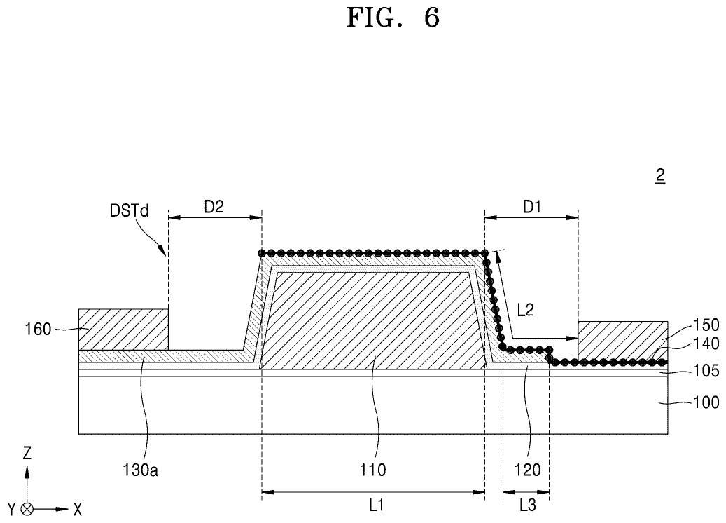

FIG. 6 is a cross-sectional view showing a semiconductor device 2 according to embodiments.

Referring to FIG. 6, the semiconductor device 2 includes a substrate 100, a gate electrode 110 above the substrate 100, a gate dielectric film 120 covering the gate electrode 110 above the substrate 100, a semiconductor channel layer 130a partially covering the gate dielectric film 120, a Dirac source layer 140 partially covering the semiconductor channel layer 130a, a source electrode 150 connected to the Dirac source layer 140, and a drain electrode 160 connected to the semiconductor channel layer 130a. The gate electrode 110, the gate dielectric film 120, the semiconductor channel layer 130a, the Dirac source layer 140, the source electrode 150, and the drain electrode 160 may constitute a Dirac source transistor DSTd. The Dirac source transistor DSTd may include an FET. In some embodiments, a base insulating layer 105 may be disposed on the substrate 100. For example, the base insulating layer 105 may be located between the substrate 100 and the gate electrode 110.

The semiconductor channel layer 130a may cover the side surfaces and the upper surface of the gate electrode 110 with the gate dielectric film 120 therebetween. The semiconductor channel layer 130a may be in contact with the lower surface of the drain electrode 160 but may not be in contact with the source electrode 150. For example, the semiconductor channel layer 130a may extend from above the gate electrode 110 in the first horizontal direction (the X direction) and be in contact with the drain electrode 160. Also, the semiconductor channel layer 130a may extend from the gate electrode 110 toward the source electrode 150 in the first horizontal direction (the X direction) but may not extend to the source electrode 150 and be spaced apart from the source electrode 150.

Each of the source electrode 150 and the drain electrode 160 may be spaced apart from the gate electrode 110 in the first horizontal direction (the X direction). For example, in the first horizontal direction (the X direction), the gate electrode 110 and the source electrode 150 may be spaced apart from each other by a first distance D1, and the gate electrode 110 and the drain electrode 160 may be spaced apart from each other by a second distance D2 that is greater than the first distance D1.

The Dirac source layer 140 may partially cover the semiconductor channel layer 130a. The Dirac source layer 140 may completely overlap the gate electrode 110 in the vertical direction (the Z direction). In the first horizontal direction (the X direction), the Dirac source layer 140 may extend from above the gate electrode 110 toward the source electrode 150. The Dirac source layer 140 may be in contact with the semiconductor channel layer 130a above the gate electrode 110. Also, the Dirac source layer 140 may extend from above the gate electrode 110 toward the source electrode 150 and be in contact with the source electrode 150. The Dirac source layer 140 may be in contact with the gate dielectric film 120 between the source electrode 150 and one end of the semiconductor channel layer 130a facing the source electrode 150 in the first horizontal direction (the X direction). For example, the Dirac source layer 140 may be in contact with the semiconductor channel layer 130a above the gate electrode 110. The Dirac source layer 140 may extend along the upper surface and side surfaces of the semiconductor channel layer 130a and the upper surface of the gate dielectric film 120 in the direction from the gate electrode 110 toward the source electrode 150 and may be in contact with the source electrode 150.

The Dirac source layer 140 may cover a portion of the semiconductor channel layer 130a that covers the upper surface of the gate electrode 110, but may not cover another portion of the semiconductor channel layer 130a that covers the side surface of the gate electrode 110 facing the drain electrode 160 in the first horizontal direction (the X direction). For example, one end of the Dirac source layer 140 facing the drain electrode 160 in the first horizontal direction (the X direction) may be aligned with one end of the gate electrode 110 in the vertical direction (the Z direction).

In an X-Z plane, a first portion of the Dirac source layer 140 that overlaps the gate electrode 110 in the vertical direction (the Z direction) may extend with a first length L1, and a second portion of the Dirac source layer 140 that extends from the first portion thereof to the source electrode 150 may extend with a second length L2. A portion of the semiconductor channel layer 130a extending from a portion thereof covering the upper surface and side surfaces of the gate electrode 110 toward the source electrode 150 may have a third length L3. The third length L3 of the semiconductor channel layer 130a may be less than the first distance D1 between the gate electrode 110 and the source electrode 150 and the second length L2 of the second portion of the Dirac source layer 140.

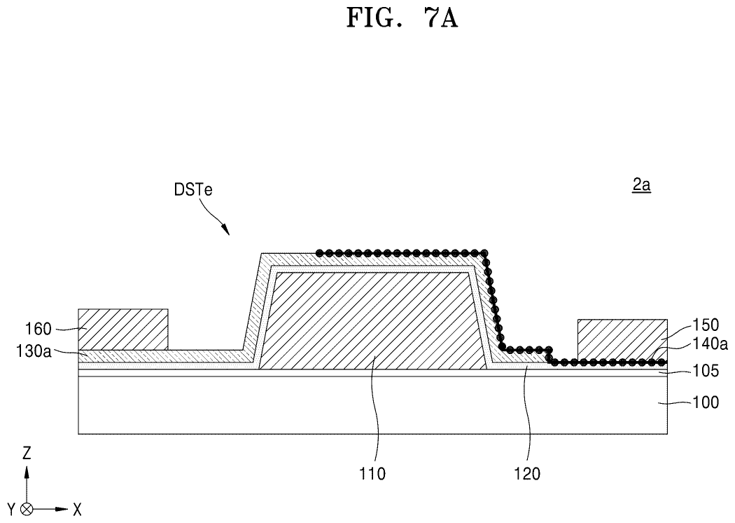

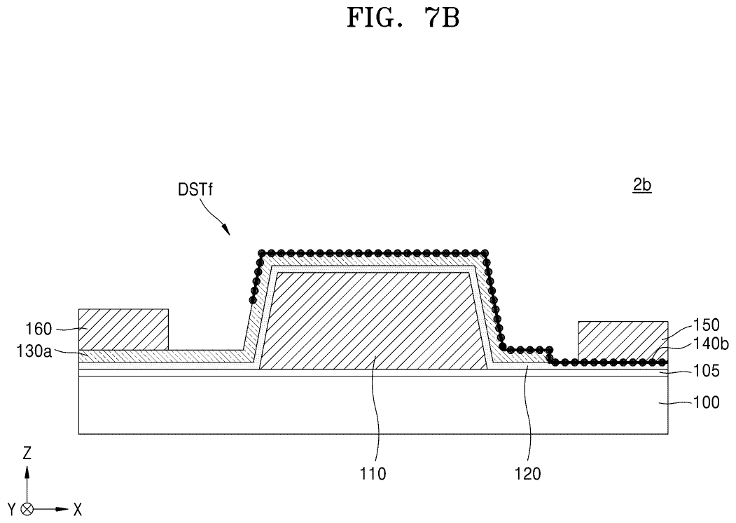

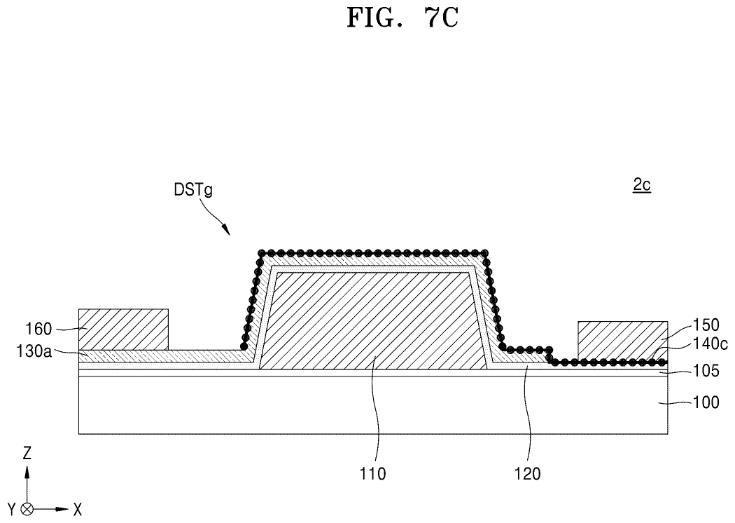

FIGS. 7A to 7C are cross-sectional views showing semiconductor devices according to embodiments.

Referring to FIG. 7A, a semiconductor device 2a includes a substrate 100, a gate electrode 110 above the substrate 100, a gate dielectric film 120 covering the gate electrode 110 above the substrate 100, a semiconductor channel layer 130a covering the gate dielectric film 120, a Dirac source layer 140a partially covering the semiconductor channel layer 130a, a source electrode 150 connected to the Dirac source layer 140a but spaced apart from the semiconductor channel layer 130a, and a drain electrode 160 connected to the semiconductor channel layer 130a. The gate electrode 110, the gate dielectric film 120, the semiconductor channel layer 130a, the Dirac source layer 140a, the source electrode 150, and the drain electrode 160 may constitute a Dirac source transistor DSTe. The Dirac source transistor DSTe may include an FET. In some embodiments, a base insulating layer 105 may be disposed on the substrate 100. For example, the base insulating layer 105 may be located between the substrate 100 and the gate electrode 110.

The semiconductor channel layer 130a may cover the side surfaces and the upper surface of the gate electrode 110 with the gate dielectric film 120 therebetween. The Dirac source layer 140a may partially cover the semiconductor channel layer 130a. The Dirac source layer 140a may overlap a portion of the gate electrode 110 in a vertical direction (a Z direction) but may not overlap the remaining portion thereof in the vertical direction (the Z direction). For example, the Dirac source layer 140a may overlap, in the vertical direction (the Z direction), a portion of the gate electrode 110 adjacent to the source electrode 150 but may not overlap, in the vertical direction (the Z direction), the remaining portion of the gate electrode 110 adjacent to the drain electrode 160.

In a first horizontal direction (an X direction), the Dirac source layer 140a may extend from above the gate electrode 110 toward the source electrode 150. The Dirac source layer 140a may be in contact with the semiconductor channel layer 130a above the gate electrode 110. Also, the Dirac source layer 140a may extend from above the gate electrode 110 toward the source electrode 150 and be in contact with the source electrode 150.

Referring to FIG. 7B, a semiconductor device 2b includes a substrate 100, a gate electrode 110 above the substrate 100, a gate dielectric film 120 covering the gate electrode 110 above the substrate 100, a semiconductor channel layer 130a covering the gate dielectric film 120, a Dirac source layer 140b partially covering the semiconductor channel layer 130a, a source electrode 150 connected to the Dirac source layer 140b but spaced apart from the semiconductor channel layer 130a, and a drain electrode 160 connected to the semiconductor channel layer 130a. The gate electrode 110, the gate dielectric film 120, the semiconductor channel layer 130a, the Dirac source layer 140b, the source electrode 150, and the drain electrode 160 may constitute a Dirac source transistor DSTf. The Dirac source transistor DSTf may include an FET. In some embodiments, a base insulating layer 105 may be disposed on the substrate 100. For example, the base insulating layer 105 may be located between the substrate 100 and the gate electrode 110.

The semiconductor channel layer 130a may cover the side surfaces and the upper surface of the gate electrode 110 with the gate dielectric film 120 therebetween. The Dirac source layer 140b may partially cover the semiconductor channel layer 130a. The Dirac source layer 140b may completely overlap the gate electrode 110 in a vertical direction (a Z direction). For example, the Dirac source layer 140b may extend from above the gate electrode 110 toward the drain electrode 160 in a first horizontal direction (an X direction). The Dirac source layer 140b may entirely cover the semiconductor channel layer 130a covering the upper surface of the gate electrode 110 and entirely cover the semiconductor channel layer 130a covering the side surface of the gate electrode 110 facing the source electrode 150 in the first horizontal direction (the X direction). Also, the Dirac source layer 140b may cover a portion of the semiconductor channel layer 130a covering the upper portion of the side surface of the gate electrode 110 facing the drain electrode 160 in the first horizontal direction (the X direction) but may not cover another portion of the semiconductor channel layer 130a covering the lower portion of the side surface of the gate electrode 110 facing the drain electrode 160 in the first horizontal direction (the X direction). A portion of the semiconductor channel layer 130a, which is located between the drain electrode 160 and the portion of the semiconductor channel layer 130 covering the upper surface and the side surface of the gate electrode 110, may be not covered by the Dirac source layer 140b. Another portion of the semiconductor channel layer 130a, which is located between the source electrode 150 and the portion of the semiconductor channel layer 130 covering the upper surface and the side surface of the gate electrode 110, may be covered by the Dirac source layer 140b.

Referring to FIG. 7C, a semiconductor device 2c includes a substrate 100, a gate electrode 110 above the substrate 100, a gate dielectric film 120 covering the gate electrode 110 above the substrate 100, a semiconductor channel layer 130a covering the gate dielectric film 120, a Dirac source layer 140c partially covering the semiconductor channel layer 130a, a source electrode 150 connected to the Dirac source layer 140c but spaced apart from the semiconductor channel layer 130a, and a drain electrode 160 connected to the semiconductor channel layer 130a. The gate electrode 110, the gate dielectric film 120, the semiconductor channel layer 130a, the Dirac source layer 140c, the source electrode 150, and the drain electrode 160 may constitute a Dirac source transistor DSTg. The Dirac source transistor DSTg may include an FET. In some embodiments, a base insulating layer 105 may be disposed on the substrate 100. For example, the base insulating layer 105 may be located between the substrate 100 and the gate electrode 110.

The semiconductor channel layer 130a may cover the side surfaces and the upper surface of the gate electrode 110 with the gate dielectric film 120 therebetween. The Dirac source layer 140c may partially cover the semiconductor channel layer 130a. The Dirac source layer 140c may completely overlap the gate electrode 110 in a vertical direction (a Z direction). For example, the Dirac source layer 140c may extend from above the gate electrode 110 toward the drain electrode 160 in a first horizontal direction (an X direction). The Dirac source layer 140c may entirely cover the semiconductor channel layer 130a covering the upper surface of the gate electrode 110, entirely cover the semiconductor channel layer 130a covering the side surface of the gate electrode 110 facing the source electrode 150 in the first horizontal direction (the X direction), and entirely cover the semiconductor channel layer 130a covering the side surface of the gate electrode 110 facing the drain electrode 160 in the first horizontal direction (the X direction). A portion of the semiconductor channel layer 130a, which is located between the drain electrode 160 and the portion of the semiconductor channel layer 130a covering the upper surface and the side surface of the gate electrode 110, may be not covered by the Dirac source layer 140c. Another portion of the semiconductor channel layer 130a, which is located between the source electrode 150 and the portion of the semiconductor channel layer 130a covering the upper surface and the side surface of the gate electrode 110, may be covered by the Dirac source layer 140c.

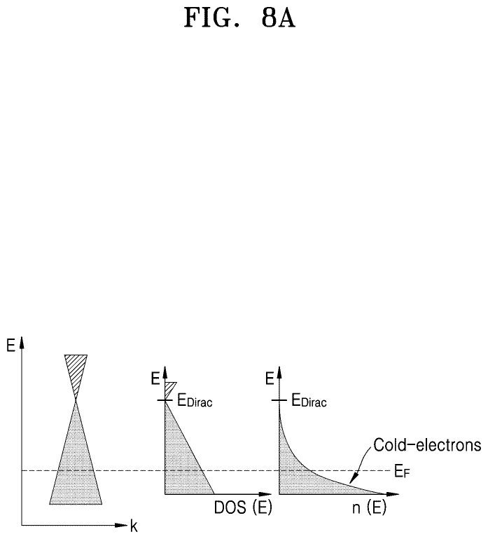

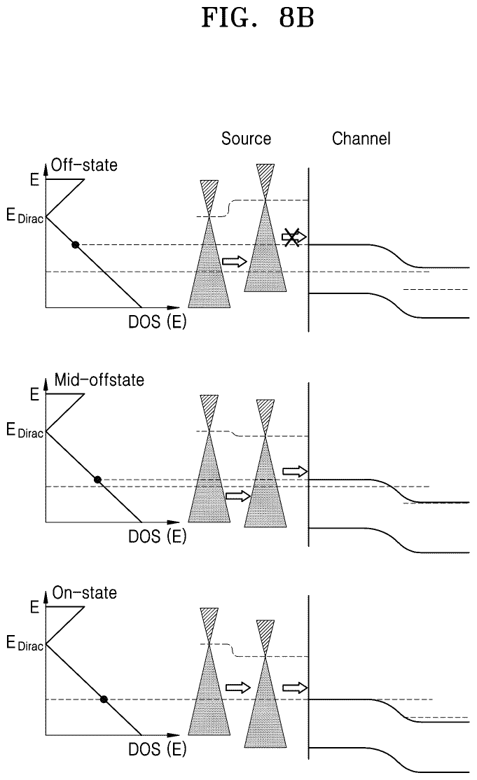

FIGS. 8A and 8B are diagrams illustrating operation principles of a semiconductor device according to embodiments.

Referring to FIGS. 8A and 8B together, when examining the relationship between kinetic energy (E) of electrons, a wave number (k), density of state (DOS), and electron concentration (n(E)) for a material constituting a Dirac source layer, the material constituting the Dirac source layer has an energy band structure with a Dirac cup-and-cone shape, and accordingly, exhibits the DOS linear with respect to the energy (E_{Dirac}: energy at the Dirac point) and shows the electron concentration that decreases super-exponentially as the energy increases. Therefore, the material described above has a significantly lower electron concentration near the fermi-level (E_{F}) than a typical source layer, and the electrons having these characteristics are referred to as cold-electrons.

Examining a switching mechanism of the Dirac source transistor in which the Dirac source layer overlaps the gate electrode, the Schottky barrier is formed between the Dirac source layer and the semiconductor channel layer. When a negative bias is applied to the gate electrode (Off-State), the Dirac source layer overlapping the gate electrode exhibits a high energy level. Accordingly, a high Schottky barrier is formed and electron injection is suppressed. When changing from Off-state to On-state (mid-off state), the Schottky barrier gradually decreases and the electron injection begins. When a positive bias is applied to the gate electrode (On-state), the Dirac point decreases in the Dirac source layer overlapping the gate electrode, and the Schottky barrier completely disappears. Accordingly, the electron injection may be facilitated and/or higher on-current may be formed.

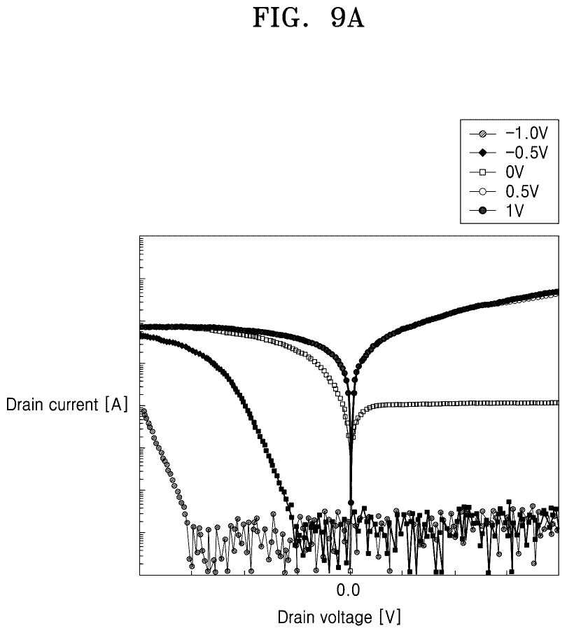

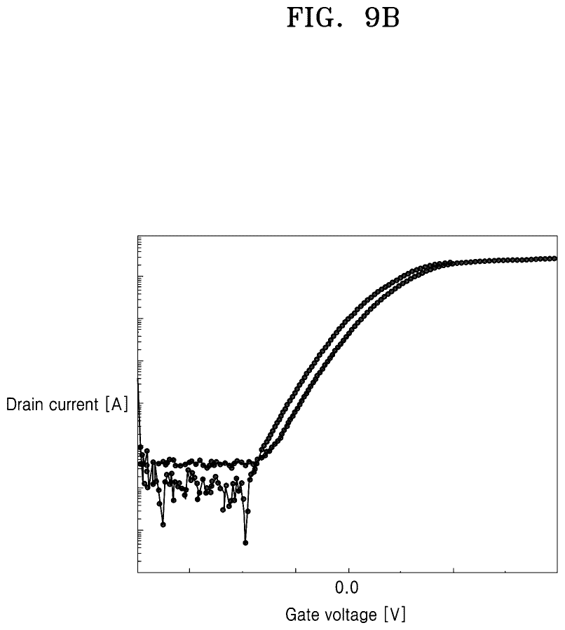

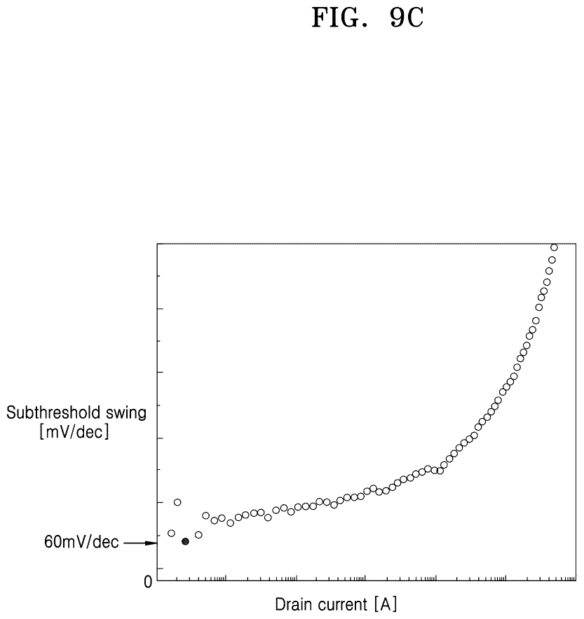

FIGS. 9A to 9C are diagrams illustrating operation characteristics of a semiconductor device according to embodiments.

FIGS. 9A to 9C show the relationship between the drain voltage and the drain current, the relationship between the gate voltage and the drain current, and the relationship between the drain current and the subthreshold swing in a Dirac source transistor. In FIGS. 9A to 9C, aluminum oxide is used as the gate dielectric film of the Dirac source transistor. The Dirac source layer exhibits a p-type at a negative gate voltage, and the Dirac source layer exhibits an n-type at a positive gate voltage. Accordingly, rectification characteristics appear with an n-type semiconductor channel layer and a negative gate voltage, but no rectification characteristics appear with a negative gate voltage (FIG. 9A). Accordingly, at VDS=0.7 V, the semiconductor channel layer exhibits n-type switching characteristics (FIG. 9B). In a subthreshold region, the low subthreshold swing value near 60 mV/dec appears.

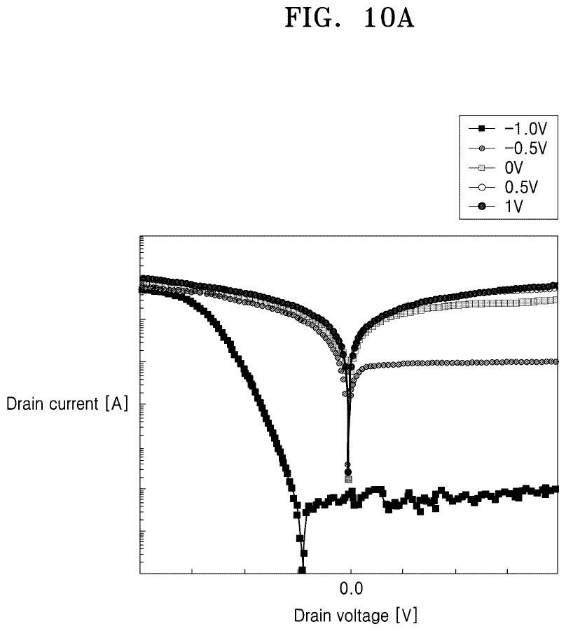

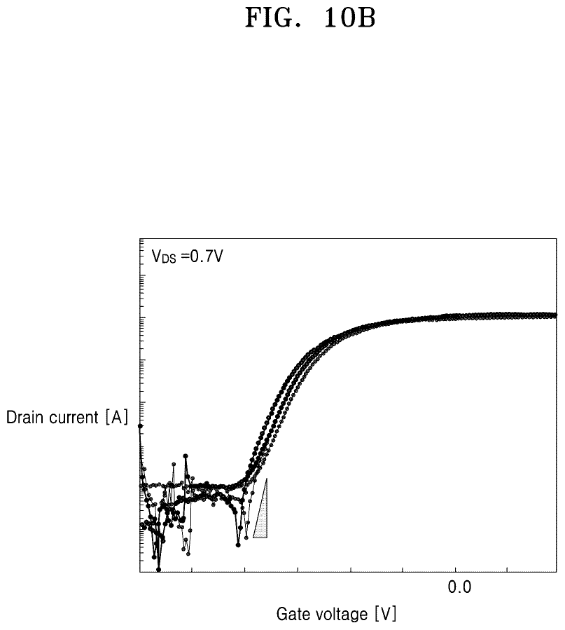

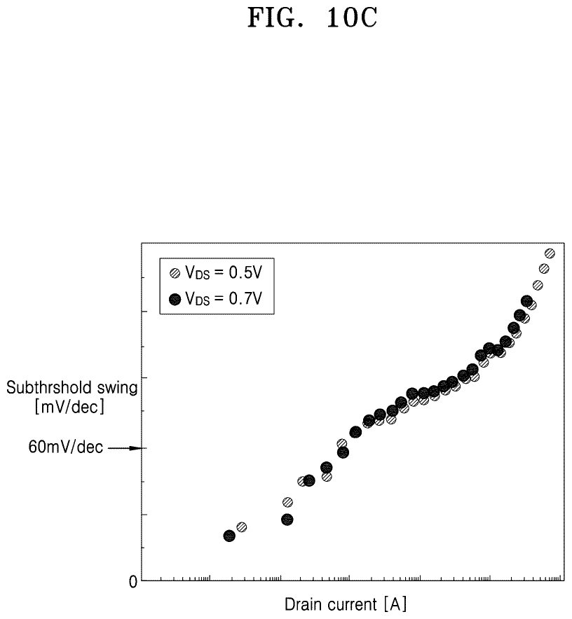

FIGS. 10A to 10C are diagrams illustrating operation characteristics of a semiconductor device according to embodiments.

FIGS. 10A to 10C show the relationship between the drain voltage and the drain current, the relationship between the gate voltage and the drain current, and the relationship between the drain current and the subthreshold swing in a Dirac source transistor. In FIGS. 10A to 10C, hafnium oxide is used as the gate dielectric film of the Dirac source transistor. The Dirac source layer exhibits a p-type at a negative gate voltage, and the Dirac source layer exhibits an n-type at a positive gate voltage. Accordingly, rectification characteristics appear with an n-type semiconductor channel layer and a negative gate voltage, but no rectification characteristics appear with a negative gate voltage (FIG. 10A). Accordingly, at VDS=0.7 V, the semiconductor channel layer exhibits n-type switching characteristics (FIG. 10B). In a subthreshold region, the lower subthreshold swing value of less than or equal to 60 mV/dec appears.

While inventive concept have been particularly shown and described with reference to embodiments thereof, it will be understood that various changes in form and details may be made therein without departing from the spirit and scope of the following claims.

What is claimed is:

1. A semiconductor device comprising:
a substrate; and
a Dirac source transistor including
a gate electrode on the substrate,
a gate dielectric film covering the gate electrode,
a semiconductor channel layer including an oxide semiconductor material and covering the gate dielectric film,
a Dirac source layer partially covering the semiconductor channel layer,
a source electrode connected to the Dirac source layer, and
a drain electrode connected to the semiconductor channel layer, wherein
the Dirac source layer at least partially overlaps the gate electrode in a vertical direction,
the Dirac source layer is spaced apart from the drain electrode, and
the Dirac source layer is not connected to the drain electrode.

2. The semiconductor device of claim 1, wherein
the semiconductor channel layer extends from above the gate electrode to below the drain electrode and is in contact with a lower surface of the drain electrode,
the Dirac source layer extends between the source electrode and the semiconductor channel layer from above the gate electrode,
the Dirac source layer is in contact with a lower surface of the source electrode,
a portion of the Dirac source layer in contact with the lower surface of the source electrode is between the lower surface of the source electrode and an upper surface of the semiconductor channel layer.

3. The semiconductor device of claim 1, wherein
the semiconductor channel layer extends from above the gate electrode to below the drain electrode and is in contact with a lower surface of the drain electrode,
the semiconductor channel layer extends from above the gate electrode toward the source electrode,
the semiconductor channel layer does not extend to the source electrode,
the semiconductor channel layer is spaced apart from the source electrode, and
the Dirac source layer is in contact with the gate dielectric film between the source electrode and one end of the semiconductor channel layer facing the source electrode.

4. The semiconductor device of claim 3, further comprising:
a base insulating layer below the gate electrode and covering the substrate.

5. The semiconductor device of claim 1, wherein
the semiconductor channel layer is doped with impurities having a first conductivity type,
the Dirac source layer is doped with impurities having a second conductivity type, and
the second conductivity type is different from the first conductivity type.

6. The semiconductor device of claim 1, wherein
a first portion of the Dirac source layer overlaps the gate electrode in the vertical direction and extends in a direction from the drain electrode toward the source electrode,
a second portion of the Dirac source layer extends from the first portion of the Dirac source layer to the source electrode, and
an extension length of the first portion of the Dirac source layer is greater than an extension length of the second portion of the Dirac source layer.

7. The semiconductor device of claim 6, wherein,
in the vertical direction, the Dirac source layer overlaps a portion of the gate electrode adjacent to the source electrode and the Dirac source layer does not overlap a remaining portion of the gate electrode adjacent to the drain electrode.

8. The semiconductor device of claim 1, wherein the Dirac source layer overlaps an entire upper surface of the gate electrode in the vertical direction.

9. The semiconductor device of claim 8, wherein one end of the Dirac source layer facing the drain electrode is aligned with one end of the gate electrode in the vertical direction.

10. The semiconductor device of claim 8, wherein the Dirac source layer extends from above the gate electrode toward the drain electrode and at least partially covers a side surface of the gate electrode facing the drain electrode.

11. A semiconductor device comprising:
a substrate; and
a Dirac source transistor including
a gate electrode on the substrate,
a gate dielectric film covering an upper surface of the gate electrode and side surfaces of the gate electrode,
a semiconductor channel layer including a three-dimensional oxide semiconductor material, the semiconductor channel layer covering the upper surface of the gate electrode and the side surface of the gate electrode with the gate dielectric film therebetween,
a Dirac source layer including a monolayer and partially covering the semiconductor channel layer,
a source electrode spaced apart from the gate electrode in a horizontal direction and connected to the Dirac source layer, and
a drain electrode spaced apart from the gate electrode in a direction opposite the horizontal direction, the drain electrode being on the semiconductor channel layer and connected to the semiconductor channel layer, wherein
the Dirac source layer at least partially covers the upper surface of the gate electrode,
the side surfaces of the gate electrode include a side surface facing the source electrode and a side surface facing the drain electrode,
the Dirac source layer covers the side surface of the gate electrode facing the source electrode, and
the Dirac source layer does not cover the side surface of the gate electrode facing the drain electrode.

12. The semiconductor device of claim 11, wherein
the source electrode is above the semiconductor channel layer, and
the Dirac source layer extends between the source electrode and the semiconductor channel layer.

13. The semiconductor device of claim 11, wherein
a first portion of the Dirac source layer extends in a direction from the gate electrode toward the source electrode and overlaps the gate electrode in a vertical direction,
a second portion of the Dirac source layer extends from the first portion of the Dirac source layer to the source electrode, and
an extension length of the second portion of the Dirac source layer is less than an extension length of the first portion of the Dirac source layer.

14. The semiconductor device of claim 13, wherein
the Dirac source layer overlaps an entire portion of the gate electrode in the vertical direction,
one end of the Dirac source layer faces the direction opposite the horizontal direction and is aligned with one end of the gate electrode in the vertical direction.

15. The semiconductor device of claim 13, wherein,
in the vertical direction, the Dirac source layer overlaps a portion of the gate electrode adjacent to the source electrode and does not overlap a remaining portion of the gate electrode adjacent to the drain electrode, and
one end of the Dirac source layer facing the direction opposite the horizontal direction and one end of the gate electrode are spaced apart from each other by a distance less than the extension length of the first portion of the Dirac source layer.

16. The semiconductor device of claim 11, wherein a thickness of the Dirac source layer is less than a thickness of the semiconductor channel layer.

17. The semiconductor device of claim 11, wherein the Dirac source layer comprises graphene.

18. A semiconductor device comprising:
a substrate; and
a Dirac source transistor including
a gate electrode on the substrate,
a gate dielectric film covering an upper surface of the gate electrode and side surfaces of the gate electrode,
a semiconductor channel layer including a three-dimensional oxide semiconductor material, the semiconductor channel layer covering the upper surface of the gate electrode and the side surfaces of the gate electrode with the gate dielectric film therebetween,
a Dirac source layer including a metallic or semi-metallic material having linear energy dispersion, the Dirac source layer partially covering the semiconductor channel layer and at least partially overlapping the gate electrode in a vertical direction,
a source electrode spaced apart from the gate electrode in a horizontal direction, the source electrode above the semiconductor channel layer and the source electrode being connected to the Dirac source layer, and
a drain electrode spaced apart from the gate electrode in a direction opposite the horizontal direction, the drain electrode being on the semiconductor channel layer and connected to the semiconductor channel layer, wherein
the semiconductor channel layer extends from above the gate electrode to below the drain electrode and the semiconductor channel layer is in contact with a lower surface of the drain electrode,
the semiconductor channel layer extends from above the gate electrode to below the source electrode,
the Dirac source layer extends between the source electrode and the semiconductor channel layer from above the gate electrode, and
a portion of the Dirac source layer is in contact with a lower surface of the source electrode and the portion of the Dirac source layer is between the lower surface of the source electrode and an upper surface of the semiconductor channel layer.

19. The semiconductor device of claim 18, wherein the Dirac source layer comprises a monolayer of graphene.

20. The semiconductor device of claim 19, wherein
the semiconductor channel layer has a thickness of 10 nm or more, and
a thickness of the Dirac source layer is less than the thickness of the semiconductor channel layer.
